(19) United States
(12) Patent Application Publication
(10) Pub. No.: US 2025/0298307 A1
(43) Pub. Date: Sep. 25, 2025

(54) METHOD FOR PATTERNING MASK LAYER USING METAL-CONTAINING RESIST

(71) Applicant: Tokyo Electron Limited, Tokyo (JP)

(72) Inventors: Katie Lutker-Lee, Albany, NY (US); Steven Grzeskowiak, Albany, NY (US); Eric Chih-Fang Liu, Albany, NY (US)

(21) Appl. No.: 18/615,346

(22) Filed: Mar. 25, 2024

(51) Int. Cl. G03F 1/80; G03F 1/60; G03F 7/16

(52) U.S. Cl. CPC G03F 1/80; G03F 1/60; G03F 7/167

(57) ABSTRACT

A method includes forming a mask layer over a substrate and forming a patterned metal-containing photoresist over the mask layer. The method further includes, using the patterned metal-containing photoresist as an etch mask, patterning the mask layer to form a plurality of features. The method further includes performing a first plasma process to remove the patterned metal-containing photoresist. The first plasma process is performed using a plasma generated from a gas mixture comprising CH₄, HBr, or hydrogen.

### TECHNICAL FIELD

The present disclosure relates generally to methods for processing a substrate and, in particular embodiments, to methods for patterning a mask layer using a metal-containing resist.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation to define a relief pattern. For example, in the case of positive photoresist, irradiated portions of the photoresist may be dissolved and removed by a developing step using a developing solvent, forming the relief pattern of the photoresist. The relief pattern then may be transferred to a target layer below the photoresist or an underlying hard mask layer formed over the target layer. Innovations on photolithographic techniques may be needed to satisfy the cost and quality requirements for patterning of nanoscale features.

### SUMMARY

In accordance with an embodiment of the present disclosure, a method for includes forming a mask layer over a substrate and forming a patterned metal-containing photoresist over the mask layer. The method further includes, using the patterned metal-containing photoresist as an etch mask, patterning the mask layer to form a plurality of features. The method further includes performing a first plasma process to remove the patterned metal-containing photoresist. The first plasma process is performed using a plasma generated from a gas mixture comprising CH₄, HBr, or hydrogen.

In accordance with an embodiment of the present disclosure, a method for includes forming a mask layer over a substrate, forming a patterned metal-containing photoresist over the mask layer, patterning the mask layer to form a plurality of features, and performing a first plasma process on the patterned metal-containing photoresist and the plurality of features. Performing the first plasma process includes removing the patterned metal-containing photoresist using a CH₄, HBr, or hydrogen based plasma. The method further includes performing a second plasma process on the plurality of features. The second plasma process is different from the first plasma process. Performing the second plasma process includes changing a width of the plurality of features.

In accordance with an embodiment of the present disclosure, a method for includes forming a carbon-containing layer over a substrate, forming a patterned metal-containing photoresist over the carbon-containing layer, and performing a first plasma process on the carbon-containing layer. Performing the first plasma process includes etching the carbon-containing layer to form a plurality of features. The method further includes performing a second plasma process on the patterned metal-containing photoresist and the plurality of features. Performing the second plasma process includes removing the patterned metal-containing photoresist using a CH₄, HBr, or hydrogen based plasma. The method further includes performing a third plasma process on the plurality of features. The third plasma process is different from the second plasma process. Performing the third plasma process includes changing a height of the plurality of features.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1H illustrate top and cross-sectional views of different stages of a method for patterning a mask layer in accordance with various embodiments;

FIG. 2 illustrates a diagram showing a dependence of an etch rate of spin-on carbon (SOC) on a flow rate of CH₄ in accordance with various embodiments;

FIG. 3 illustrates a diagram showing a dependence of a height of features of a patterned mask on a cycle number of a plasma process in accordance with various embodiments;

FIG. 4 illustrates a diagram showing a dependence of a width of features of a patterned mask on a cycle number of a plasma process in accordance with various embodiments;

FIG. 5 illustrates a diagram showing a dependence of roughness of features of a patterned mask on a cycle number of a plasma process in accordance with various embodiments;

FIG. 6 illustrates a process flow diagram of a method for patterning a mask layer in accordance with various embodiments; and

FIG. 7 illustrates a process flow diagram of a plasma process in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

As scaling continues and high numerical aperture (NA) EUV lithography is introduced, metal-containing photoresists (e.g., metal organic photoresists) are becoming a more and more popular choice for lithography. Because of their metal content, these photoresists typically require an additional step for strip or removal, unlike their only organic containing predecessors. This step needs to not degrade a roughness, width, profile, or a height of patterned mask features while still fully removing the metal-containing photoresists from the patterned mask features.

The present disclosure allows for removing metal-containing photoresists from patterned mask features by performing one or more plasma processes using a CH₄, HBr, and/or hydrogen based plasma. In various embodiments, a plasma process may be performed during or after patterning a mask layer to form patterned mask features. The plasma process may be a continuous process or a cyclic process. By tuning process parameters (e.g., plasma chemistry, flow rate, or number of cycles) of the plasma process, a roughness, width, profile and/or height of the patterned mask features can be simultaneously controlled, resulting in a better pattern fidelity.

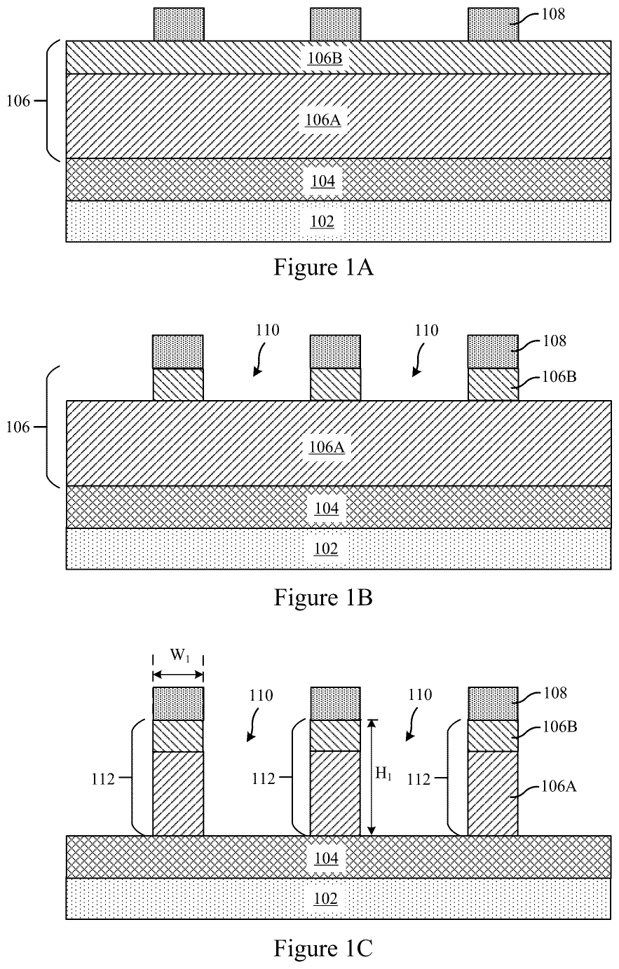

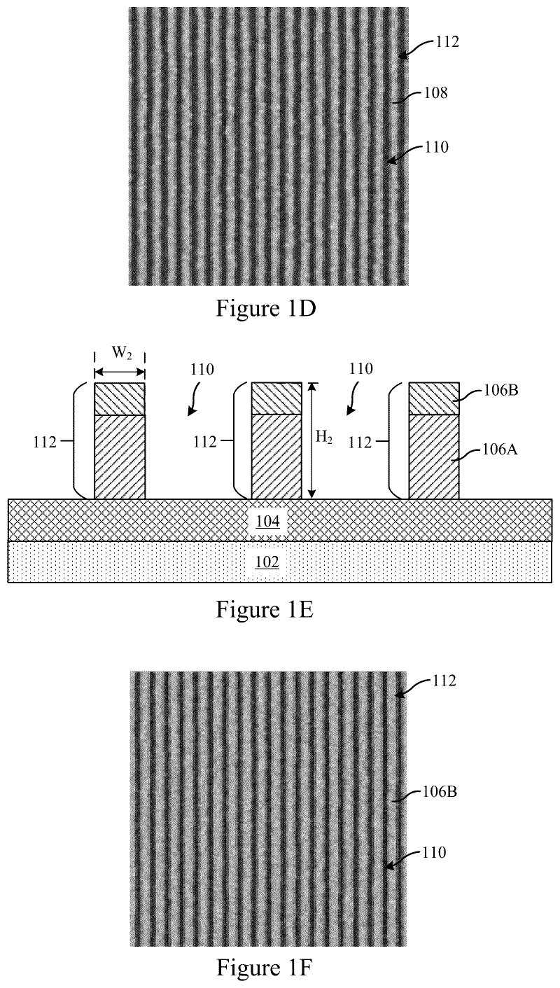

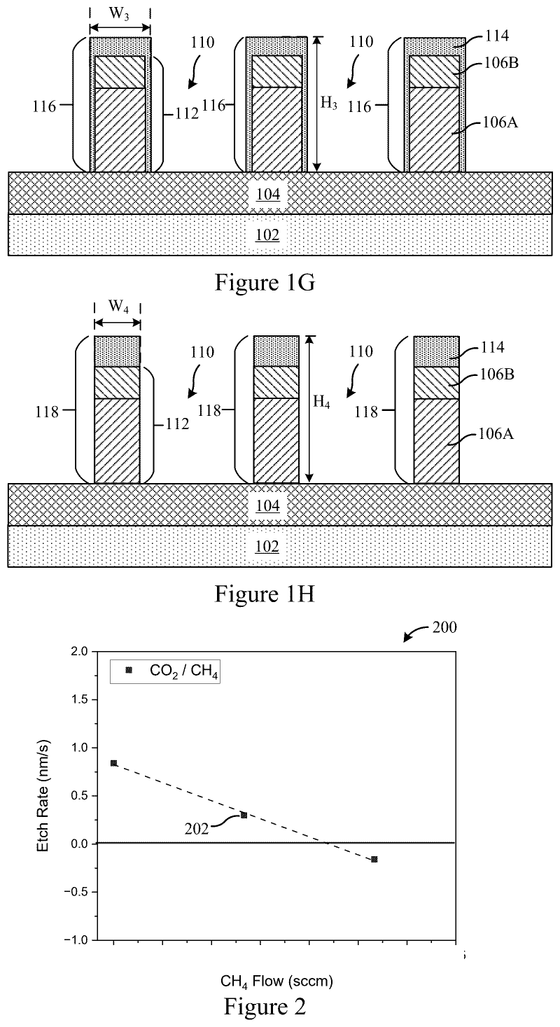

FIGS. 1A-1H illustrate top and cross-sectional views of different stages of a method for patterning a mask layer 106 in accordance with various embodiments. In particular, FIGS. 1A-1C, 1E, 1G, and 1H illustrate cross-sectional views, and FIGS. 1D and 1F illustrate top views. Referring to FIG. 1A, the mask layer 106 is formed over a substrate 102. The mask layer 106 may comprise silicon-containing anti-reflective coating (Si-ARC), spin-on glass (SOG), silicon carbon (SiC), backside anti-reflective coating (BARC) such as Si-BARC, low temperature oxide (LTO), organic planarization layer (OPL), spin-on carbon (SOC), a combination thereof, a multilayer thereof, or the like. The mask layer 106 may be a stacked mask layer comprising, for example, two or more layers of two or more different materials. In embodiments when the mask layer 106 comprises two layers (e.g., layers 106A and 106B), a first layer (e.g., layer 106A) of the mask layer 106 may comprise a carbon-containing material such as SOC, OPL, or the like, and a second layer (e.g., layer 106B) of the mask layer 106 may comprise a silicon-containing material such as Si-ARC, Si-BARC, SiC, or the like. In such embodiments, the first layer (e.g., layer 106A) of the mask layer 106 may be also referred to as a carbon-containing layer and the second layer (e.g., layer 106B) of the mask layer 106 may be also referred to as a silicon-containing layer.

The substrate 102 may be a part of, or include, a semiconductor device or a semiconductor structure, and may be formed in any suitable manner, including using any suitable combination of wet and/or dry deposition, photolithography and etch techniques. For example, the semiconductor structure may comprise the substrate 102 in which various device regions are formed. In such embodiments, the substrate 102 may include isolation regions such as shallow trench isolation (STI) regions, diffusion regions, as well as other regions formed therein.

The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or other compound semiconductors. In other embodiments, the substrate 102 may comprise heterogeneous layers such as silicon germanium on silicon, gallium nitride on silicon, silicon carbon on silicon, or layers of silicon on a silicon or SOI substrate. In various embodiments, the substrate 102 is patterned or embedded in other components of the semiconductor device or the semiconductor structure.

Referring further to FIG. 1A, in some embodiments, an intermediate layer 104 is formed over the substrate 102 such that the mask layer 106 is formed over the intermediate layer 104. The intermediate layer 104 may be a target for pattern transfer in subsequent processing after the patterning of the mask layer 106 is completed. The intermediate layer 104 may comprise a dielectric material, a metallic material, a semiconductor material, or the like, and may be formed using suitable deposition techniques such as chemical vapor deposition (CVD), atomic layer deposition (ALD), physical vapor deposition (RVD), plasma-enhanced CVD (PECVD), plasma-enhanced ALD (PEALD), spin-on deposition, combinations thereof, or the like.

In some embodiments, a patterned photoresist layer 108 is formed over the mask layer 106. In some embodiments, the patterned photoresist layer 108 may be formed by forming a photoresist layer (not shown) over the mask layer 106 and patterning the photoresist layer using suitable photolithographic techniques. The photoresist layer may comprise a positive-tone photoresist or a negative-tone photoresist. In some embodiments, the photoresist layer may comprise metal-containing photoresist materials such as metal organic resist (MOR) materials or the like. The metal-containing photoresist materials may include a Sn-containing photoresist material, W-containing photoresist material, In-containing photoresist material, Hf-containing photoresist material, Zr-containing photoresist material, Zn-containing photoresist material, or the like.

The photoresist layer may be deposited on the substrate 102 in any suitable manner. For example, the photoresist layer may be deposited by spin-coating, spray-coating, dip-coating, or roll-coating. As a particular example, the photoresist layer may be deposited on the substrate 102 using a spin-on deposition technique, which may be also referred to as spin-coating. In other embodiments, the photoresist layer may be deposited using PVD, CVD, PECVD, a combination thereof, or the like. In various embodiments, the photoresist layer may comprise an agent-generating ingredient that, in response to a suitable agent-activation trigger (e.g., heat or radiation), generates a solubility-changing agent (e.g., an acid). Example agent-generating ingredients may include a thermal-acid generator (TAG) that is configured to generate an acid in response to heat or a photo-acid generator (PAG) that is configured to generate an acid in response to actinic radiation. In other embodiments, the photoresist layer may be free of an agent-generating ingredient.

After forming the photoresist layer, a reticle (not shown) is disposed over the photoresist layer. The reticle may be used to modulate a dose (or an intensity) of a radiation (e.g., actinic radiation) that is used to expose the photoresist layer. In such embodiments, the reticle may comprise regions of different transparency to the radiation (e.g., opaque and transparent regions). The photoresist layer is then subject to an exposure step through the reticle. The radiation exposes exposed regions of the photoresist layer while unexposed (or unmodified) regions of the photoresist layer are protected by the reticle. The exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), extreme UV (EUV) lithography, deep UV (DUV) lithography, high numerical aperture (NA) EUV lithography, or any suitable photolithography technology.

In some embodiments, the radiation generates an acid in the exposed regions of the photoresist layer. The acid may be generated from the PAG that is present in the photoresist layer under the influence of the radiation. The acid may react with the material of the photoresist layer and alter the solubility of the exposed regions of the photoresist layer. Subsequently, in embodiments when the photoresist layer is a positive-tone photoresist, the exposed regions of the photoresist layer are removed by performing a developing process using a suitable developer. The developing process forms a plurality of openings in the photoresist layer that expose portions of the mask layer 106. The unexposed regions of the photoresist layer form the patterned photoresist layer 108. In embodiments when the photoresist layer is a negative-tone photoresist, the unexposed regions of the photoresist layer are removed by performing a developing process using a suitable developer and the unexposed regions of the photoresist layer form the patterned photoresist layer 108.

Referring to FIG. 1B, a patterning process is performed on the second layer 106B of the mask layer 106 to transfer a pattern of the patterned photoresist layer 108 to the second layer 106B of the mask layer 106. The patterning process forms a plurality of openings 110 in the second layer 106B of the mask layer 106 such that the openings 110 expose the first layer 106A of the mask layer 106. In some embodiments, the patterning process may include an etch process such as a reactive ion etch (RIE) process while using the patterned photoresist layer 108 as an etch mask.

Referring to FIG. 1C, a patterning process is performed on the first layer 106A of the mask layer 106 to transfer the pattern of the patterned photoresist layer 108 to the first layer 106A of the mask layer 106. The patterning process extends the plurality of openings 110 into the first layer 106A of the mask layer 106 such that the openings 110 expose the intermediate layer 104. Remaining portions of the first layer 106A and the second layer 106B form a plurality of features 112. In some embodiments, the features 112 are elongated parallel features extending along a top surface of the intermediate layer 104. In such embodiments, the features 112 may be also referred to as lines. In some embodiments, the patterning process may comprise a first plasma process performed using CO, CO₂, O₂, SO₂, CH₄, or HBr based plasma. In such embodiments, the first plasma process is performed using a plasma generated from a gas mixture comprising CO, CO₂, O₂, SO₂, CH₄, or HBr. The first plasma process may be a direct plasma process or a remote plasma process. The first plasma process may be an inductively-coupled plasma (ICP) process, a capacitively-coupled plasma (CCP) process, or the like. In some embodiments, the first plasma process may be performed at a process temperature in a range from −70° C. to 120° C. and a process pressure in a range from 5 mtorr to 500 mtorr. In some embodiments, the features 112 may have a width W₁ in a range from 5 nm to 100 nm. The features 112 may have a height H₁.

FIG. 1D illustrates a top view of the structure of FIG. 1C in accordance with some embodiments. In particular, FIG. 1D illustrates a critical dimension scanning electron microscopy (CDSEM) image. In the illustrated embodiment, the features 112 are elongated parallel features separated by the opening 110. The opening 110 may be also referred to as trenches. In some embodiments, sidewalls (also referred to as edges) of the features 112 have line edge roughness (LER) in a range from 3 nm to 3.5 nm.

Referring to FIG. 1E, the patterned photoresist layer 108 (see FIG. 1C) is removed from the features 112. In some embodiments, the removal process may comprise a second plasma process performed using CH₄, HBr, or hydrogen based plasma. In such embodiments, the second plasma process is performed using a plasma generated from a gas mixture comprising CH₄, HBr, or hydrogen. The second plasma process may be a direct plasma process or a remote plasma process. The second plasma process may be an inductively-coupled plasma (ICP) process, a capacitively-coupled plasma (CCP) process, or the like. In some embodiments, the second plasma process may be a continuous process. In other embodiments, the second plasma process may be a cyclic process. In such embodiments, a cycle of the second plasma process comprises a deposition process followed by a trim process. In some embodiments, the second plasma process may be cycled between the deposition and trim processes by tuning parameters of the second plasma process, such as a flow rate of a plasma generating chemicals, for example. In some embodiments, the second plasma process may be performed at a process temperature in a range from −70° C. to 150° C. and a process pressure in a range from 5 mtorr to 500 mtorr.

Referring further to FIG. 1E, in some embodiments, the second plasma process may be stopped as soon as the patterned photoresist layer 108 is removed. In addition to removing the patterned photoresist layer 108, the second plasma process may adjust (or alter) a LER of the sidewalls (also referred to as edges) of the features 112 and a width of the features 112. In some embodiments, the features 112 may have a width W₂ in a range from 5 nm to 100 nm. In some embodiments, the width W₂ is less than the width W₁ (see FIG. 1C). In other embodiments, the width W₂ is greater than or equal to the width W₁ (see FIG. 1C). The features 112 may have a height H₂. In some embodiments, the height H₂ is less than the height H₁ (see FIG. 1C). In other embodiments, the height H₂ is greater than or equal to the height H₁ (see FIG. 1C). In some embodiments, the width W₂ and/or height H₂ of the features 112 may not have desired target values after performing the second plasma process.

FIG. 1F illustrates a top view of the structure of FIG. 1E in accordance with some embodiments. In particular, FIG. 1F illustrates a CDSEM image. In the illustrated embodiment, the features 112 are elongated parallel features separated by the opening 110. In some embodiments, the LER of the sidewalls (also referred to as edges) of the features 112 before performing the second plasma process in greater than the LER of the sidewalls (also referred to as edges) of the features 112 after performing the second plasma process.

Referring to FIG. 1G, in some embodiments when the width W₂, the height H₂ of the features 112, and/or the LER of the sidewalls (also referred to as edges) of the features 112 do not have desired target values, a third plasma process may be performed on the features 112 (see FIG. 1E) to adjust dimensions and roughness of the features 112 to form features 116. In some embodiments, the third plasma process may be performed using CH₄ or hydrogen based plasma. In such embodiments, the first plasma process is performed using a plasma generated from a gas mixture comprising CH₄ or hydrogen. The third plasma process may be a direct plasma process or a remote plasma process. The third plasma process may be an inductively-coupled plasma (ICP) process, a capacitively-coupled plasma (CCP) process, or the like. In some embodiments, the third plasma process may be a continuous process. In other embodiments, the third plasma process may be a cyclic process. In such embodiments, a cycle of the third plasma process comprises a deposition process followed by a trim process. In some embodiments, the third plasma process may be cycled between the deposition and trim processes by tuning parameters of the third plasma process, such as a flow rate of a plasma generating chemicals. In some embodiments, the number of cycles of the third plasma process may be tuned such that a target roughness and target dimensions for the features 116 are achieved. In some embodiments, the third plasma process may be performed at a process temperature in a range from −70° C. to 150° C. and a process pressure in a range from 5 mtorr to 500 mtorr.

In some embodiments, the number of cycles of the third plasma process may be tuned such that a material 114 may be deposited on tops and the sidewalls of the features 112 to form the features 116. The material 114 may comprise a carbon-containing material. In some embodiments, the features 116 may have a width W₃ in a range from 5 nm to 100 nm. In the illustrated embodiment, the width W₃ is greater than the width W₂ (see FIG. 1E). In some embodiments, the features 116 may have a height H₃. In the illustrated embodiment, the height H₃ is greater than the height H₂ (see FIG. 1E). In some embodiments, after performing the third plasma process, the sidewalls (also referred to as edges) of the features 116 have LER improved (reduced) from the previous step.

Referring to FIG. 1H, in some embodiments, the number of cycles of the third plasma process may be tuned such that the material 114 may be deposited on tops of the features 112 and a material may be removed from the sidewalls of the features 112, thereby forming features 118. In some embodiments, the features 118 may have a width W₄ in a range from 5 nm to 100 nm. In the illustrated embodiment, the width W₄ is less than the width W₂ (see FIG. 1E). In some embodiments, the features 118 may have a height H₄. In the illustrated embodiment, the height H₄ is greater than the height H₂ (see FIG. 1E). In some embodiments, after performing the third plasma process, the sidewalls (also referred to as edges) of the features 118 have improved (reduced) from the previous step.

In some embodiments, the second plasma process (see FIG. 1E) is different from the first plasma process (see FIG. 1C) and is performed after performing the first plasma process. In such embodiments, the removal process described above with reference to FIG. 1E is performed after performing the patterning process described above with reference to FIG. 1C. In other embodiments, instead of performing two different plasma processes, a single plasma process is performed on the structure of FIG. 1B to simultaneously pattern the mask layer 106 to form the features 112 (see FIG. 1E) and remove the patterned photoresist layer 108.

In some embodiments, the third plasma process (see FIGS. 1G and 1H) is different from the second plasma process (see FIG. 1E) and is performed after performing the second plasma process. In such embodiments, the pattern adjustment process described above with reference to FIGS. 1G and 1H is performed after performing the removal process described above with reference to FIG. 1E. In other embodiments, instead of performing two different plasma processes, a single plasma process is performed on the structure of FIG. 1C to simultaneously remove the patterned photoresist layer 108 and adjust a roughness, width, and/or height of the features 112 to form the features 116 (see FIG. 1G) or the features 118 (see FIG. 1H).

In some embodiments, the first plasma process (see FIG. 1C), the second plasma process (see FIG. 1E) and the third plasma process (see FIGS. 1G and 1H) are different plasma processes that are performed sequentially. In other embodiments, instead of performing three different plasma processes, a single plasma process is performed on the structure of FIG. 1B to simultaneously pattern the mask layer 106 to form the features 112 (see FIG. 1E), remove the patterned photoresist layer 108, and adjust a roughness, width, and/or height of the features 112 to form the features 116 (see FIG. 1G) or the features 118 (see FIG. 1H).

In some embodiments when the single plasma process is performed instead of the first plasma process (see FIG. 1C) and the second plasma process (see FIG. 1E), the single plasma process may be performed using CH₄, HBr, or hydrogen based plasma. In such embodiments, the single plasma process is performed using a plasma generated from a gas mixture comprising CH₄, HBr, or hydrogen. The single plasma process may be a direct plasma process or a remote plasma process. The single plasma process may be an inductively-coupled plasma (ICP) process, a capacitively-coupled plasma (CCP) process, or the like. In some embodiments, the single plasma process may be a continuous process. In other embodiments, the single plasma process may be a cyclic process. In such embodiments, a cycle of the single plasma process comprises a deposition process followed by a trim process. In some embodiments, the single plasma process may be cycled between the deposition and trim processes by tuning parameters of the single plasma process, such as a flow rate of a plasma generating chemicals, for example. In some embodiments, the number of cycles of the single plasma process may be tuned such that a target roughness and target dimensions for the features 116 (see FIG. 1G) or 118 (see FIG. 1H) are achieved. In some embodiments, the single plasma process may be performed at a process temperature in a range from −70° C. to 150° C. and a process pressure in a range from 5 mtorr to 500 mtorr.

In some embodiments when the single plasma process is performed instead of the second plasma process (see FIG. 1E) and the third plasma process (see FIGS. 1G and 1H), the single plasma process may be performed using CH₄ or hydrogen based plasma. In such embodiments, the single plasma process is performed using a plasma generated from a gas mixture comprising CH₄ or hydrogen. The single plasma process may be a direct plasma process or a remote plasma process. The single plasma process may be an inductively-coupled plasma (ICP) process, a capacitively-coupled plasma (CCP) process, or the like. In some embodiments, the single plasma process may be a continuous process. In other embodiments, the single plasma process may be a cyclic process. In such embodiments, a cycle of the single plasma process comprises a deposition process followed by a trim process. In some embodiments, the single plasma process may be cycled between the deposition and trim processes by tuning parameters of the single plasma process, such as a flow rate of a plasma generating chemicals, for example. In some embodiments, the number of cycles of the single plasma process may be tuned such that a target roughness and target dimensions for the features 116 (see FIG. 1G) or 118 (see FIG. 1H) are achieved. In some embodiments, the single plasma process may be performed at a process temperature in a range from −70° C. to 150° C. and a process pressure in a range from 5 mtorr to 500 mtorr.

In some embodiments when the single plasma process is performed instead of the first plasma process (see FIG. 1C), the second plasma process (see FIG. 1E) and the third plasma process (see FIGS. 1G and 1H), the single plasma process may be performed using CH₄ or hydrogen based plasma. In such embodiments, the single plasma process is performed using a plasma generated from a gas mixture comprising CH₄ or hydrogen. The single plasma process may be a direct plasma process or a remote plasma process. The single plasma process may be an inductively-coupled plasma (ICP) process, a capacitively-coupled plasma (CCP) process, or the like. In some embodiments, the single plasma process may be a continuous process. In other embodiments, the single plasma process may be a cyclic process. In such embodiments, a cycle of the single plasma process comprises a deposition process followed by a trim process. In some embodiments, the single plasma process may be cycled between the deposition and trim processes by tuning parameters of the single plasma process, such as a flow rate of a plasma generating chemicals, for example. In some embodiments, the number of cycles of the single plasma process may be tuned such that a target roughness and target dimensions for the features 116 (see FIG. 1G) or 118 (see FIG. 1H) are achieved. In some embodiments, the single plasma process may be performed at a process temperature in a range from −70° C. to 150° C. and a process pressure in a range from 5 mtorr to 500 mtorr.

FIG. 2 illustrates a diagram 200 showing a dependence of an etch rate (indicated by full squares 202) of SOC in a plasma process performed using a CH₄ based plasma on a flow rate of CH₄ in accordance with various embodiments. In the diagram, the positive etch rate indicates removal of a material, while the negative etch rate indicates addition of a material. In the illustrated embodiment, the etch rate decreases from a positive value to a negative value as the flow rate of CH₄ increases. The plasma process may be configured as a deposition process by tuning the flow rate of CH₄ to a first flow rate such that the etch rate has a negative value. The plasma process may be configured as a trim process by tuning the flow rate of CH₄ to a second flow rate such that the etch rate has a positive value. In the illustrated embodiments, the second flow rate is less than the first flow rate.

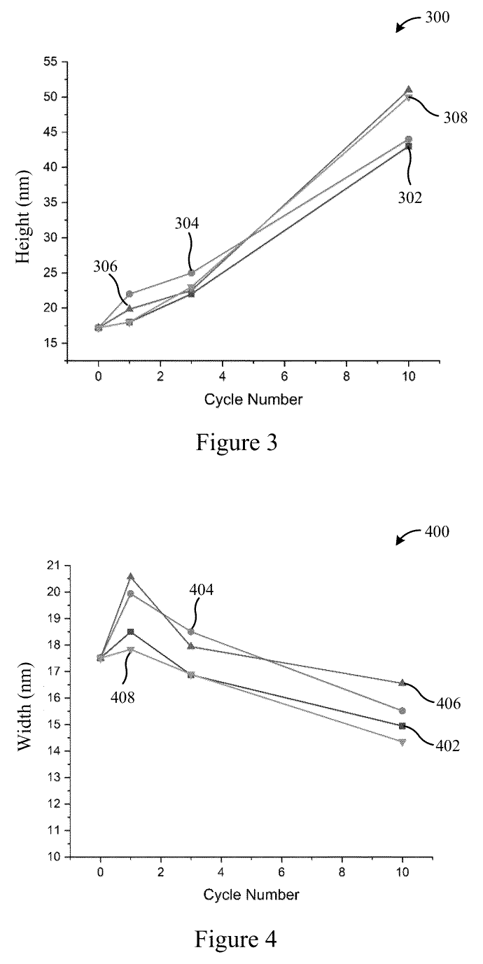

FIG. 3 illustrates a diagram 300 showing a dependence of a height of features (e.g., features 116 of FIG. 1G or features 118 of FIG. 1H) on a cycle number of the third plasma process (see FIGS. 1G and 1H) in accordance with various embodiments. Curves 302-308 corresponds to different ratios of a deposition duration to a trim duration. The curves 302-308 show that the height of the features (e.g., features 116 of FIG. 1G or features 118 of FIG. 1H) increases as the cycle number increases. In some embodiments, the cycle number may be tuned to achieve a target height for the features (e.g., features 116 of FIG. 1G or features 118 of FIG. 1H).

FIG. 4 illustrates a diagram 400 showing a dependence of a width of features (e.g., features 116 of FIG. 1G or features 118 of FIG. 1H) on a cycle number of the third plasma process (see FIGS. 1G and 1H) in accordance with various embodiments. Curves 402-408 corresponds to different ratios of a deposition duration to a trim duration. The curves 402-408 show that the width of the features (e.g., features 116 of FIG. 1G) increases as the cycle number increases from 1 to 2. The curves 402-408 further show that the width of the features (e.g., features 118 of FIG. 1H) decreases for the cycle numbers greater than or equal to 3. In some embodiments, the cycle number may be tuned to achieve a target width for the features (e.g., features 116 of FIG. 1G or features 118 of FIG. 1H).

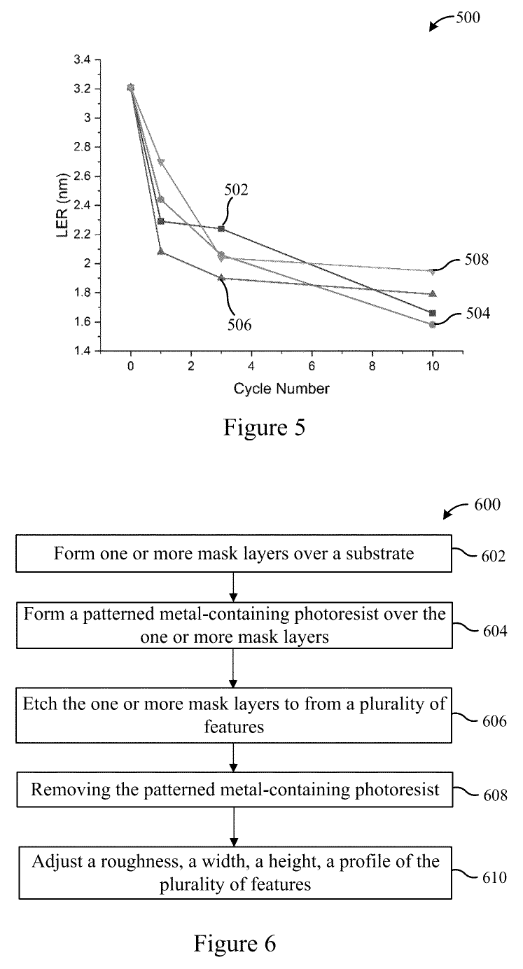

FIG. 5 illustrates a diagram 500 showing a dependence of a LER of features (e.g., features 116 of FIG. 1G or features 118 of FIG. 1H) on the cycle number of the third plasma process (see FIGS. 1G and 1H) in accordance with various embodiments. Curves 502-508 corresponds to different ratios of a deposition duration to a trim duration. The curves 502-508 show that the LER of the features (e.g., features 116 of FIG. 1G or features 118 of FIG. 1H) decreases as the cycle number increases. In some embodiments, the cycle number may be tuned to achieve a target LER for the features (e.g., features 116 of FIG. 1G or features 118 of FIG. 1H).

FIG. 6 illustrates a process flow diagram of a method 600 for patterning a mask layer (e.g., the mask layer 106 of FIG. 1A) in accordance with various embodiments. Method 600 start with step 602. In step 602, one or more mask layers (e.g., mask layers 106 of FIG. 1A) are formed over a substrate (e.g., substrate 102) as described above with reference to FIG. 1A. In step 604, a patterned metal-containing photoresist (e.g., patterned photoresist layer 108 of FIG. 1A) is formed over the one or more mask layers (e.g., mask layer 106 of FIG. 1A) as described above with reference to FIG. 1A. In step 606, the one or more mask layers (e.g., mask layer 106 of FIG. 1A) are etched to form a plurality of features (e.g., features 112 of FIG. 1C) as described above with reference to FIGS. 1B and 1C. In step 608, the patterned metal-containing photoresist (e.g., patterned photoresist layer 108 of FIG. 1C) is removed as described above with reference to FIG. 1E. In step 610, a roughness, width, height, and/or profile of the plurality of features (e.g., features 116 of FIG. 1G or features 118 of FIG. 1H) are adjusted as described above with reference to FIGS. 1G and 1H.

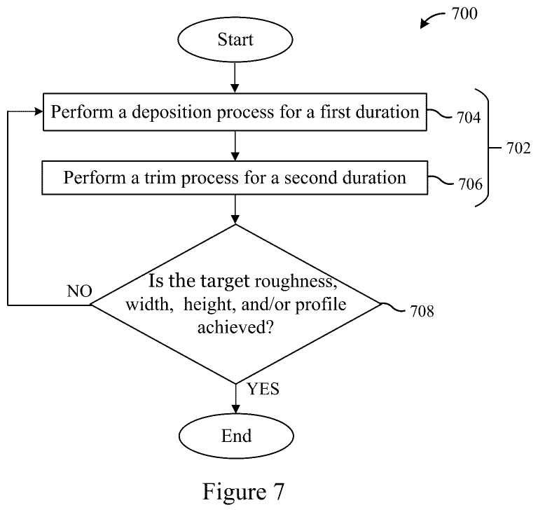

In some embodiment, performing step 606 comprises performing a first plasma process, performing step 608 comprises performing a second plasma process different from the first plasma process, and performing step 610 comprises performing a third plasma process different from the first plasma process and the second plasma process. Each of the first plasma process, the second plasma process, and the third plasma process may be implemented by a plasma process 700 described below with reference to FIG. 7. In other embodiments, performing steps 606 and 608 comprises performing a single plasma process. In such embodiments, the single plasma process may be implemented by the plasma process 700 described below with reference to FIG. 7. In yet other embodiments, performing steps 608 and 610 comprises performing a single plasma process. In such embodiments, the single plasma process may be implemented by the plasma process 700 described below with reference to FIG. 7. In yet other embodiments, performing steps 606, 608, and 610 comprises performing a single plasma process. In such embodiments, the single plasma process may be implemented by the plasma process 700 described below with reference to FIG. 7.

FIG. 7 illustrates a process flow diagram of a plasma process 700 in accordance with various embodiments. Plasma process 700 starts with step 702. In step 702, a plasma process cycle is performed. In some embodiments, step 702 comprises steps 704 and 706. In step 704, a deposition process is performed for a first duration. In some embodiments, the first duration is in a range from 2 sec to 120 sec. The deposition process may comprise a plasma process performed using CH₄ or hydrogen based plasma. In such embodiments, the plasma process is performed using a plasma generated from a gas mixture comprising CH₄ or hydrogen. The plasma process may be a direct plasma process or a remote plasma process. The plasma process may be an inductively-coupled plasma (ICP) process, a capacitively-coupled plasma (CCP) process, or the like. In some embodiments, the plasma process may be performed at a process temperature in a range from −70° C. to 150° C. and a process pressure in a range from 5 mtorr to 500 mtorr. In some embodiments, a flow rate of a plasma generating chemicals (e.g., CH₄) are tuned such that the plasma process performs the deposition process. In step 706, a trim process is performed for a second duration. In some embodiments, the second duration is in a range from 2 sec to 120 sec. In some embodiments, the second duration is different from the first duration. The trim process may comprise a plasma process performed using CH₄ or hydrogen based plasma. In such embodiments, the plasma process is performed using a plasma generated from a gas mixture comprising CH₄ or hydrogen. The plasma process may be a direct plasma process or a remote plasma process. The plasma process may be an inductively-coupled plasma (ICP) process, a capacitively-coupled plasma (CCP) process, or the like. In some embodiments, the plasma process may be performed at a process temperature in a range from −70° C. to 150° C. and a process pressure in a range from 5 mtorr to 500 mtorr. In some embodiments, a flow rate of a plasma generating chemicals (e.g., CH₄) are tuned such that the plasma process performs the trim process. In step 708, it is determined whether a target roughness, width, height, and/or profile are achieved for the patterned features. In some embodiments, the determination process comprises determining a number of performed plasma process cycles. In response to determining at step 708 that the target roughness, width, height, and/or profile are not achieved, plasma process 700 proceeds to step 704. In some embodiments, steps 704-708 may be performed one or more times until the target roughness, width, height, and/or profile are achieved. In response to determining at step 708 that the target roughness, width, height, and/or profile are achieved, plasma process 700 proceeds to end.

Example embodiments of the disclosure are summarized below. Other embodiments can also be understood from the entirety of the specification as well as the claims filed herein.

Example 1. A method includes forming a mask layer over a substrate and forming a patterned metal-containing photoresist over the mask layer. The method further includes, using the patterned metal-containing photoresist as an etch mask, patterning the mask layer to form a plurality of features. The method further includes performing a first plasma process to remove the patterned metal-containing photoresist. The first plasma process is performed using a plasma generated from a gas mixture comprising CH₄, HBr, or hydrogen.

Example 2. The method of example 1, where patterning the mask layer includes exposing the mask layer to a second plasma process.

Example 3. The method of one of examples 1 and 2, where performing the first plasma process further includes changing a width of the plurality of features.

Example 4. The method of one of examples 1 to 3, where performing the first plasma process further includes changing a height of the plurality of features.

Example 5. The method of one of examples 1 to 4, where the first plasma process includes one or more cycles. Each cycle includes performing a deposition process for a first duration and performing a trim process for a second duration different from the first duration.

Example 6. The method of one of examples 1 to 5, where performing the deposition process includes performing a first CH₄ plasma process. The first CH₄ plasma process is performed with a first CH₄ flow rate.

Example 7. The method of one of examples 1 to 6, where performing the trim process includes performing a second CH₄ plasma process. The second CH₄ plasma process is performed with a second CH₄ flow rate less than the first CH₄ flow rate.

Example 8. A method includes forming a mask layer over a substrate, forming a patterned metal-containing photoresist over the mask layer, patterning the mask layer to form a plurality of features, and performing a first plasma process on the patterned metal-containing photoresist and the plurality of features. Performing the first plasma process includes removing the patterned metal-containing photoresist using a CH₄, HBr, or hydrogen based plasma. The method further includes performing a second plasma process on the plurality of features. The second plasma process is different from the first plasma process. Performing the second plasma process includes changing a width of the plurality of features.

Example 9. The method of example 8, where performing the second plasma process further includes increasing a height of the plurality of features.

Example 10. The method of one of examples 8 and 9, where performing the second plasma process further includes reducing a roughness of sidewall of the plurality of features.

Example 11. The method of one of examples 8 to 10, where the first plasma process is performed using an HBr based plasma.

Example 12. The method of one of examples 8 to 11, where the first plasma process is performed using a CH₄ based plasma.

Example 13. The method of one of examples 8 to 12, where changing the width of the plurality of features includes reducing the width of the plurality of features.

Example 14. The method of one of examples 8 to 13, where changing the width of the plurality of features includes increasing the width of the plurality of features.

Example 15. A method includes forming a carbon-containing layer over a substrate, forming a patterned metal-containing photoresist over the carbon-containing layer, and performing a first plasma process on the carbon-containing layer. Performing the first plasma process includes etching the carbon-containing layer to form a plurality of features. The method further includes performing a second plasma process on the patterned metal-containing photoresist and the plurality of features. Performing the second plasma process includes removing the patterned metal-containing photoresist using a CH₄, HBr, or hydrogen based plasma. The method further includes performing a third plasma process on the plurality of features. The third plasma process is different from the second plasma process. Performing the third plasma process includes changing a height of the plurality of features.

Example 16. The method of example 15, where performing the second plasma process further includes reducing a roughness of sidewall of the plurality of features.

Example 17. The method of one of examples 15 and 16, where performing the second plasma process further includes changing a width of the plurality of features.

Example 18. The method of one of examples 15 to 17, where the third plasma process includes one or more cycles. Each cycle includes performing a deposition process on the plurality of features for a first duration and performing a trim process on the plurality of features for a second duration different from the first duration.

Example 19. The method of one of examples 15 to 18, where the deposition process is performed by changing a flow rate of plasma generating chemicals of the third plasma process to a first flow rate.

Example 20. The method of one of examples 15 to 19, where the trim process is performed by changing the flow rate of the plasma generating chemicals of the third plasma process to a second flow rate less than the first flow rate.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method of forming a device, the method comprising:
forming a mask layer over a substrate;
forming a patterned metal-containing photoresist over the mask layer;
using the patterned metal-containing photoresist as an etch mask, patterning the mask layer to form a plurality of features; and
performing a first plasma process to remove the patterned metal-containing photoresist, wherein the first plasma process is performed using a plasma generated from a gas mixture comprising CH₄, HBr, or hydrogen.

2. The method of claim 1, wherein patterning the mask layer comprises exposing the mask layer to a second plasma process.

3. The method of claim 1, wherein performing the first plasma process further comprises changing a width of the plurality of features.

4. The method of claim 1, wherein performing the first plasma process further comprises changing a height of the plurality of features.

5. The method of claim 1, wherein the first plasma process comprises one or more cycles, wherein each cycle comprises:
performing a deposition process for a first duration; and
performing a trim process for a second duration different from the first duration.

6. The method of claim 5, wherein performing the deposition process comprises performing a first CH₄ plasma process, wherein the first CH₄ plasma process is performed with a first CH₄ flow rate.

7. The method of claim 6, wherein performing the trim process comprises performing a second CH₄ plasma process, wherein the second CH₄ plasma process is performed with a second CH₄ flow rate less than the first CH₄ flow rate.

8. A method comprising:
forming a mask layer over a substrate;
forming a patterned metal-containing photoresist over the mask layer;
patterning the mask layer to form a plurality of features;
performing a first plasma process on the patterned metal-containing photoresist and the plurality of features, wherein performing the first plasma process comprises removing the patterned metal-containing photoresist using a CH₄, HBr, or hydrogen based plasma; and
performing a second plasma process on the plurality of features, wherein the second plasma process is different from the first plasma process, and wherein performing the second plasma process comprises changing a width of the plurality of features.

9. The method of claim 8, wherein performing the second plasma process further comprises increasing a height of the plurality of features.

10. The method of claim 8, wherein performing the second plasma process further comprises reducing a roughness of sidewall of the plurality of features.

11. The method of claim 8, wherein the first plasma process is performed using an HBr based plasma.

12. The method of claim 8, wherein the first plasma process is performed using a CH₄ based plasma.

13. The method of claim 8, wherein changing the width of the plurality of features comprises reducing the width of the plurality of features.

14. The method of claim 8, wherein changing the width of the plurality of features comprises increasing the width of the plurality of features.

15. A method comprising:
forming a carbon-containing layer over a substrate;
forming a patterned metal-containing photoresist over the carbon-containing layer;
performing a first plasma process on the carbon-containing layer, wherein performing the first plasma process comprises etching the carbon-containing layer to form a plurality of features;
performing a second plasma process on the patterned metal-containing photoresist and the plurality of features, wherein performing the second plasma process comprises removing the patterned metal-containing photoresist using a CH₄, HBr, or hydrogen based plasma; and
performing a third plasma process on the plurality of features, wherein the third plasma process is different from the second plasma process, and wherein performing the third plasma process comprises changing a height of the plurality of features.

16. The method of claim 15, wherein performing the second plasma process further comprises reducing a roughness of sidewall of the plurality of features.

17. The method of claim 15, wherein performing the second plasma process further comprises changing a width of the plurality of features.

18. The method of claim 15, wherein the third plasma process comprise one or more cycles, wherein each cycle comprises:
performing a deposition process on the plurality of features for a first duration; and
performing a trim process on the plurality of features for a second duration different from the first duration.

19. The method of claim 18, wherein the deposition process is performed by changing a flow rate of plasma generating chemicals of the third plasma process to a first flow rate.

20. The method of claim 19, wherein the trim process is performed by changing the flow rate of the plasma generating chemicals of the third plasma process to a second flow rate less than the first flow rate.
